(19) United States
(12) Patent Application Publication
(10) Pub. No.: US 2025/0285829 A1
(43) Pub. Date: Sep. 11, 2025

(54) ION IMPLANTER AND ION IMPLANTATION METHOD

(71) Applicant: Sumitomo Heavy Industries Ion Technology Co., Ltd., Tokyo (JP)

(72) Inventor: Taisei FUTAKUCHI, Ehime (JP)

(21) Appl. No.: 19/216,837

(22) Filed: May 23, 2025

Related U.S. Application Data
(63) Continuation of application No. PCT/JP2023/040051, filed on Nov. 7, 2023.

(30) Foreign Application Priority Data
Dec. 2, 2022 (JP) 2022-193557

(51) Int. Cl. H01J 37/147; H01J 37/08; H01J 37/09; H01J 37/317

(52) U.S. Cl. CPC H01J 37/1477; H01J 37/08; H01J 37/09; H01J 37/3171; H01J 2237/057

(57) ABSTRACT

An ion implanter includes an ion source that generates ions, an extraction unit that extracts the ions from the ion source to generate an ion beam, a mass spectrometry unit that deflects the ion beam in a horizontal direction, a beam scanning unit that is configured to perform reciprocating scanning in a scanning direction, which is different from the horizontal direction, with the ion beam having passed through the mass spectrometry unit to generate a scanning beam, and a holding device that is configured to hold a workpiece and to reciprocate the workpiece, which is held by the holding device, in a direction crossing the scanning beam.

### CROSS-REFERENCE TO RELATED APPLICATIONS

This is a bypass continuation of International PCT Application No. PCT/JP2023/040051, filed on Nov. 7, 2023, which claims priority to Japanese Patent Application No. 2022-193557, filed on Dec. 2, 2022, which are incorporated by reference herein in their entirety.

### BACKGROUND

### Technical Field

Certain embodiments of the present disclosure relate to an ion implanter and an ion implantation method.

### Description of Related Art

In a semiconductor device manufacturing process, a process of implanting ions into a semiconductor wafer (also referred to as an ion implantation process) is typically performed for the purpose of changing the conductivity of a semiconductor, changing a crystal structure of the semiconductor, or the like. An ion implanter that is configured to scan a wafer as a workpiece in a horizontal direction with an ion beam and to reciprocate the wafer in a vertical direction in order to implant ions into an entire surface of the wafer is known in the related art.

### SUMMARY

According to an aspect of the present disclosure, there is provided an ion implanter including an ion source that generates ions, an extraction unit that extracts the ions from the ion source to generate an ion beam, a mass spectrometry unit that deflects the ion beam in a horizontal direction, a beam scanning unit that is configured to perform reciprocating scanning in a scanning direction, which is different from the horizontal direction, with the ion beam having passed through the mass spectrometry unit to generate a scanning beam, and a holding device that is configured to hold a workpiece and to reciprocate the workpiece, which is held by the holding device, in a direction crossing the scanning beam.

According to another aspect of the present disclosure, there is provided an ion implantation method. The method includes generating ions using an ion source, extracting the ions from the ion source to generate an ion beam, deflecting the ion beam in a horizontal direction to perform mass spectrometry, performing reciprocating scanning in a scanning direction, which is different from the horizontal direction, with the ion beam having been subjected to the mass spectrometry to generate a scanning beam, and reciprocating a workpiece in a direction crossing the scanning beam.

### BRIEF DESCRIPTION OF THE DRAWINGS

FIG. 1 is a top view showing a schematic configuration of an ion implanter according to an embodiment.

FIG. 2 is a side view showing the schematic configuration of the ion implanter according to the embodiment.

FIG. 3 is a front view showing a schematic configuration of a first holding device and a second holding device.

FIGS. 4A and 4B are top views schematically showing an orientation of a first workpiece, which is held by the first holding device, in a horizontal direction.

FIGS. 5A to 5C are side views schematically showing an orientation of the first workpiece, which is held by the first holding device, in a vertical direction.

FIG. 6 is a front view showing an example of operations of the first holding device and the second holding device.

FIG. 7 is a front view showing an example of the operations of the first holding device and the second holding device.

FIG. 8 is a front view showing an example of the operations of the first holding device and the second holding device.

FIG. 9 is a front view showing an example of the operations of the first holding device and the second holding device.

FIG. 10 is a flowchart showing a flow of an ion implantation method according to an embodiment.

FIG. 11 is a flowchart showing a flow of an ion implantation method according to a modification example.

### DETAILED DESCRIPTION

It is preferable to further improve the productivity of the ion implantation process in which the ion implanter is used.

It is desirable to provide a technique for improving the productivity of an ion implantation process.

Any combination of the above-described components or a replacement of the components and expressions of the present disclosure between methods, devices, systems, and the like is also effective as an aspect of the present disclosure.

Configurations of an ion implanter and mode for performing an ion implantation method according to embodiments of the present disclosure will be described in detail below with reference to the drawings. In the description of the drawings, the same elements will be denoted by the same reference numerals and repeated description thereof will be omitted as appropriate. Further, configurations described below are merely examples, and do not limit the scope of the present invention in any way.

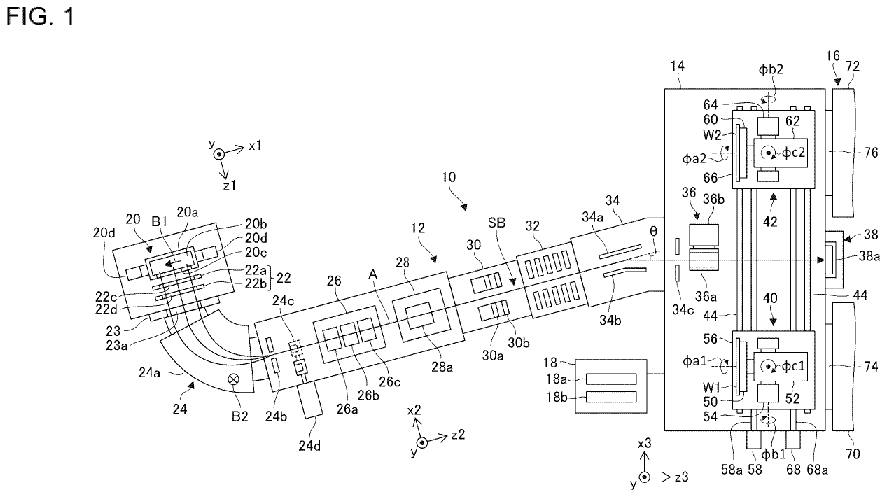

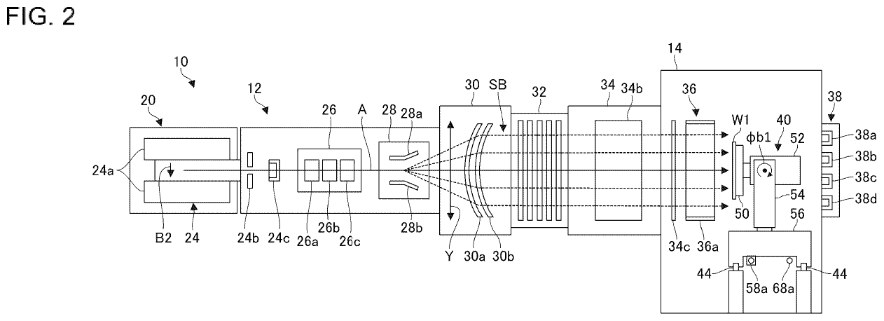

FIG. 1 is a top view showing a schematic configuration of an ion implanter 10 according to the embodiment. FIG. 2 is a side view showing the schematic configuration of the ion implanter 10 according to the embodiment. The ion implanter 10 is configured to perform ion implantation processing on the surfaces of workpieces W1 and W2. The workpieces W1 and W2 are, for example, substrates, and are, for example, semiconductor wafers. For convenience of description, the workpiece is referred to as a “substrate” or a “wafer” in the present specification. However, this is not intended to limit an object to be subjected to the implantation processing to a specific object. The workpiece may be a large substrate (for example, a glass substrate or a resin substrate) used to manufacture a flat panel display (FPD).

The ion implanter 10 is configured to irradiate the entire processing target surfaces of the workpieces W1 and W2 with a spot-like ion beam by performing reciprocating scanning in a predetermined scanning direction with the ion beam and reciprocating the workpieces W1 and W2 in a direction intersecting the scanning direction. The ion implanter 10 includes a beam generation device 12, an implantation processing chamber 14, a transport device 16, and a control device 18.

The beam generation device 12 is configured to generate an ion beam and to transport the ion beam to the implantation processing chamber 14. The implantation processing chamber 14 accommodates the workpieces W1 and W2 to be subjected to the implantation processing. In the implantation processing chamber 14, the workpieces W1 and W2 are irradiated with the ion beam provided from the beam generation device 12. The transport device 16 is configured to transport the workpieces W1 and W2, which are not yet subjected to the implantation processing, into the implantation processing chamber 14 and to transport the workpieces W1 and W2, which have been subjected to the implantation processing, out of the implantation processing chamber 14. The control device 18 is configured to control the overall operation of various devices constituting the ion implanter 10. The ion implanter 10 includes a vacuum evacuation system (not shown) for providing a desired vacuum environment to the beam generation device 12, the implantation processing chamber 14, and the transport device 16.

The beam generation device 12 includes an ion source 20, an extraction unit 22, a mass spectrometry unit 24, a beam shaping unit 26, a beam scanning unit 28, a beam collimation unit 30, an acceleration/deceleration unit 32, and an energy filter unit 34 in order from an upstream side of a beamline A. Here, the beamline A is used for convenience of description, and is synonymous with a beam trajectory ideal in design in a case where the workpieces are not scanned with an ion beam by the beam scanning unit 28. Further, an upstream of the beamline A refers to a side close to the ion source 20, and a downstream of the beamline A refers to a side close to the implantation processing chamber 14 (or a beam stopper 38).

The beam generation device 12 is configured such that the beamline A is bent in the middle. A traveling direction of the beamline A is changed in the mass spectrometry unit 24 and the energy filter unit 34. The beamline A is formed to extend in a horizontal plane perpendicular to a vertical direction. In the present specification, for convenience of description, a traveling direction of an ion beam traveling along the beamline A is defined as a z direction, the vertical direction is defined as a y direction, and a direction perpendicular to the y direction and the z direction is defined as an x direction. In particular, a traveling direction of the beamline A from the ion source 20 to the mass spectrometry unit 24 is defined as a z1 direction, and a direction perpendicular to the y direction and the z1 direction is defined as an x1 direction. Further, a traveling direction of the beamline A from the mass spectrometry unit 24 to the energy filter unit 34 is defined as a z2 direction, and a direction perpendicular to the y direction and the z2 direction is defined as an x2 direction. Furthermore, a traveling direction of the beamline A downstream of the energy filter unit 34 is defined as a z3 direction, and a direction perpendicular to the y direction and the z3 direction is defined as an x3 direction.

The ion source 20 is configured to generate ions that form an ion beam. The ion source 20 includes an arc chamber 20a. The arc chamber 20a includes an internal space 20b in which plasma is generated. The arc chamber 20a has the shape of a substantially rectangular parallelepiped box that defines the internal space 20b. The arc chamber 20a includes a front slit 20c for extracting ions from the plasma generated in the internal space 20b. The front slit 20c has the shape of a slit of which an opening width in a horizontal direction (x1 direction) is long and an opening width in the vertical direction (y direction) is short. That is, the opening width of the front slit 20c in the horizontal direction is larger than the opening width of the front slit 20c in the vertical direction.

The ion source 20 includes a source magnet device 20d. The source magnet device 20d is configured to apply a magnetic field B1, which is parallel to the horizontal direction (x1 direction), to the internal space 20b of the arc chamber 20a. The source magnet device 20d applies the magnetic field B1 to improve the generation efficiency of the plasma that is generated in the internal space 20b of the arc chamber 20a. A direction in which the magnetic field B1 is applied by the source magnet device 20d corresponds to a longitudinal direction of the front slit 20c.

The extraction unit 22 is provided downstream of the ion source 20. The extraction unit 22 extracts ions from the ion source 20 to generate the ion beam. The extraction unit 22 is configured to extract ions from the plasma generated in the internal space 20b of the arc chamber 20a. The extraction unit 22 includes a first extraction electrode 22a and a second extraction electrode 22b. The first extraction electrode 22a is provided on the downstream side of the arc chamber 20a, and the second extraction electrode 22b is provided on the downstream side of the first extraction electrode 22a. A negative suppression voltage is applied to the first extraction electrode 22a. A ground voltage is applied to the second extraction electrode 22b. A positive extraction voltage is applied to the arc chamber 20a.

The first extraction electrode 22a includes a first extraction opening 22c through which the ion beam passes. The first extraction opening 22c has the shape of a slit of which an opening width in the horizontal direction (x1 direction) is long and an opening width in the vertical direction (y direction) is short, like the front slit 20c. That is, the opening width of the first extraction opening 22c in the horizontal direction is larger than the opening width of the first extraction opening 22c in the vertical direction. The second extraction electrode 22b includes a second extraction opening 22d through which the ion beam passes. The second extraction opening 22d has the shape of a slit of which an opening width in the horizontal direction (x1 direction) is long and an opening width in the vertical direction (y direction) is short, like the front slit 20c. That is, the opening width of the second extraction opening 22d in the horizontal direction is larger than the opening width of the second extraction opening 22d in the vertical direction.

The ion beam extracted by the extraction unit 22 may be a ribbon-like beam that spreads in the horizontal direction (x1 direction). In a case where the opening widths of the front slit 20c, the first extraction opening 22c, and the second extraction opening 22d in the horizontal direction are increased, the size of the ribbon-like beam in the horizontal direction can be increased. As a result, it is easy to increase the beam current of the ion beam that is extracted from the ion source 20.

The mass spectrometry unit 24 is provided downstream of the extraction unit 22. The mass spectrometry unit 24 is configured to select a necessary ion species from the ion beam, which is extracted by the extraction unit 22, using mass spectrometry. The mass spectrometry unit 24 includes a mass spectrometry magnet device 24a, a mass resolving aperture 24b, and an injector Faraday cup 24c.

The mass spectrometry magnet device 24a applies a magnetic field B2 to the ion beam and deflects the ion beam along a different path according to a value of a mass-to-charge ratio (M=m/q, m is mass, and q is charge) of the ions. The mass spectrometry magnet device 24a applies the magnetic field B2, which is parallel to the vertical direction (-y direction), and deflects the ion beam in the horizontal direction (x1 direction). The intensity of the magnetic field B2 applied by the mass spectrometry magnet device 24a is adjusted such that an ion species having a desired mass-to-charge ratio M passes through the mass resolving aperture 24b. The ion beam passing through the mass resolving aperture 24b is deflected by, for example, 90 degrees by the mass spectrometry magnet device 24a.

The mass resolving aperture 24b is provided downstream of the mass spectrometry magnet device 24a. The mass resolving aperture 24b has the shape of a slit of which an opening width in the horizontal direction (x2 direction) is short and an opening width in the vertical direction (y direction) is long. That is, the opening width of the mass resolving aperture 24b in the vertical direction is larger than the opening width of the mass resolving aperture 24b in the horizontal direction.

The mass resolving aperture 24b may be configured such that an opening width (that is, a slit width) in the horizontal direction (x2 direction) is variable to adjust a mass resolution. The mass resolving aperture 24b may be configured to include two beam shield members that are movable in a slit width direction, and may be configured such that the slit width can be adjusted with a change in an interval between the two beam shield members. The mass resolving aperture 24b may be configured such that the mass resolving aperture 24b is switched to any one of a plurality of slits having different slit widths to make the slit width variable.

The injector Faraday cup 24c is provided downstream of the mass resolving aperture 24b. The injector Faraday cup 24c measures the beam current of the ion beam that passes through the mass resolving aperture 24b and has been subjected to mass spectrometry. The injector Faraday cup 24c can measure a mass spectrum of the ion beam by measuring the beam current while changing the intensity of the magnetic field of the mass spectrometry magnet device 24a. The measured mass spectrum can be used to calculate the mass resolution of the mass spectrometry unit 24.

The injector Faraday cup 24c is configured to be movable into and out of the beamline A with an operation of an injector drive unit 24d. The injector drive unit 24d moves the injector Faraday cup 24c in a direction perpendicular to the z2 direction in which the beamline A extends (for example, the x2 direction). In a case where the injector Faraday cup 24c is disposed on the beamline A as shown by a broken line in FIG. 1, the injector Faraday cup 24c blocks the ion beam directed to the downstream side. On the other hand, in a case where the injector Faraday cup 24c retreats from the beamline A as shown by a solid line in FIG. 1, the blocking of the ion beam directed to the downstream side is released.

A magnetic shield 23 may be provided between the extraction unit 22 and the mass spectrometry unit 24. The magnetic shield 23 is configured to suppress magnetic field interference between the magnetic field B1 applied in the ion source 20 and the magnetic field B2 applied in the mass spectrometry unit 24. The magnetic shield 23 is made of a magnetic material such as an electromagnetic steel plate. The magnetic shield 23 includes a passage opening 23a through which the ion beam traveling from the extraction unit 22 toward the mass spectrometry unit 24 passes. The passage opening 23a may have the shape of a slit of which an opening width in the horizontal direction (x1 direction) is long and an opening width in the vertical direction (y direction) is short, like the front slit 20c. That is, the opening width of the passage opening 23a in the horizontal direction may be larger than the opening width of the passage opening 23a in the vertical direction.

The beam shaping unit 26 is provided downstream of the mass spectrometry unit 24. The beam shaping unit 26 is configured to shape the ion beam, which has passed through the mass spectrometry unit 24, into a desired cross-sectional shape and a desired convergence/divergence angle. The beam shaping unit 26 includes a lens device that adjusts at least one of the cross-sectional shape and the convergence/divergence angle of the ion beam. For example, the beam shaping unit 26 is configured to focus the ribbon-like ion beam, which spreads in the horizontal direction, to shape the ion beam into a spot-like ion beam.

The beam shaping unit 26 includes a plurality of lens devices, for example, three lens devices 26a, 26b, and 26c. The three lens devices 26a to 26c are configured as, for example, an electric field type three-stage quadrupole lens (also referred to as a triplet Q-lens). Since the plurality of the lens devices are used as the beam shaping unit 26 in combination, the beam shaping unit 26 can independently adjust the convergence or the divergence of the ion beam in each of the horizontal direction (x2 direction) and the vertical direction (y direction). The beam shaping unit 26 may include a magnetic field type lens device. The beam shaping unit 26 may include a lens device that shapes an ion beam using both an electric field and a magnetic field.

The beam scanning unit 28 is provided downstream of the beam shaping unit 26. The beam scanning unit 28 is configured to perform reciprocating scanning in a predetermined scanning direction with the ion beam to generate a scanning beam SB. The beam scanning unit 28 can also be referred to as a beam deflector that deflects the ion beam shaped by the beam shaping unit 26 in a predetermined scanning direction. The beam scanning unit 28 is configured such that a scanning direction is a direction different from the horizontal direction, and is configured such that, for example, the scanning direction is the vertical direction (y direction).

The beam scanning unit 28 includes a pair of scanning electrodes 28a and 28b facing each other in the vertical direction (y direction). The pair of scanning electrodes 28a and 28b is connected to a variable-voltage power supply (not shown). In a case where a voltage applied between the pair of scanning electrodes 28a and 28b is periodically changed, an electric field generated between the pair of scanning electrodes 28a and 28b is changed to deflect the ion beam at various angles. As a result, the entire scanning range in the vertical direction (y direction) is scanned with the ion beam. In FIG. 2, the scanning direction and the scanning range of the ion beam are illustrated by an arrow Y and a plurality of trajectories of the ion beam in the scanning range are shown by broken lines. The beam scanning unit 28 may be of a magnetic field type instead of an electric field type. The beam scanning unit 28 may include a magnet device for deflecting the ion beam.

The beam collimation unit 30 is provided downstream of the beam scanning unit 28. The beam collimation unit 30 is configured such that the traveling direction of the ion beam with which the reciprocating scanning has been performed by the beam scanning unit 28 is parallel to a direction of the beamline A. The beam collimation unit 30 includes a plurality of arc-shaped collimating lens electrodes 30a and 30b that are provided with passage slits for the ion beam in middle portions thereof in the horizontal direction (x2 direction). The collimating lens electrodes 30a and 30b are connected to a high-voltage power supply (not shown), and causes an electric field, which is generated by the application of a high voltage, to act on the ion beam to make the traveling directions of the ion beam parallel to each other. The beam collimation unit 30 may be of a magnetic field type instead of an electric field type. The beam collimation unit 30 may include a magnet device for deflecting the ion beam.

The acceleration/deceleration unit 32 is provided downstream of the beam collimation unit 30. The acceleration/deceleration unit 32 is configured to accelerate or decelerate the scanning beam that is collimated by the beam collimation unit 30. The acceleration/deceleration unit 32 is an electrostatic acceleration/deceleration device, and accelerates or decelerates the ion beam using a potential difference between a first potential applied to an upstream side of the acceleration/deceleration unit 32 and a second potential applied to a downstream side of the acceleration/deceleration unit 32. The energy filter unit 34 is provided downstream of the

acceleration/deceleration unit 32. The energy filter unit 34 is configured to analyze the energy of the ion and to allow ions having a desired energy to pass therethrough toward the implantation processing chamber 14. The energy filter unit 34 is an angle energy filter (AEF) that deflects the ion beam in the horizontal direction and selects desired energy depending on a deflection angle θ of the ion beam. The deflection angle θ is, for example, 10 degrees or more and 20 degrees or less, and is about 15 degrees. The energy filter unit 34 includes a pair of AEF electrodes 34a and 34b and an energy resolving aperture 34c.

The pair of AEF electrodes 34a and 34b is disposed to face each other in a direction perpendicular to the scanning direction. The pair of AEF electrodes 34a and 34b is disposed to face each other in the horizontal direction (the x2 direction or the x3 direction). The pair of AEF electrodes 34a and 34b is connected to a high-voltage power supply (not shown) and causes an electric field to act on the ion beam to deflect the ion beam. The pair of AEF electrodes 34a and 34b is a deflector that deflects the scanning beam in the horizontal direction. The energy resolving aperture 34c is provided downstream of the pair of AEF electrodes 34a and 34b.

The energy resolving aperture 34c has the shape of a slit of which an opening width in the vertical direction (y direction) is long and an opening width in the horizontal direction (x3 direction) is short. That is, the opening width of the energy resolving aperture 34c in the vertical direction is larger than the opening width of the energy resolving aperture 34c in the horizontal direction. The energy resolving aperture 34c allows the ion, which has a desired energy value or a desired energy range, to pass therethrough toward the workpieces W1 and W2, and blocks the other ion.

The energy filter unit 34 may be of a magnetic field type instead of an electric field type. The energy filter unit 34 may include a magnet device for deflection using a magnetic field. The energy filter unit 34 may use both an electric field and a magnetic field, and may include a pair of AEF electrodes for deflection using an electric field and a magnet device for deflection using a magnetic field.

In this way, the beam generation device 12 supplies the ion beam, with which the workpieces W1 and W2 are to be irradiated, into the implantation processing chamber 14. The beam generation device 12 may be called a beamline unit. The beam generation device 12 is configured to adjust operation parameters of various devices constituting the beam generation device 12 to generate an ion beam for realizing desired implantation conditions.

The implantation processing chamber 14 includes a plasma shower device 36, a beam stopper 38, a first holding device 40, and a second holding device 42.

The plasma shower device 36 is positioned downstream of the energy filter unit 34. The plasma shower device 36 supplies low-energy electrons to the ion beam and the surfaces (processing target surfaces) of the workpieces W1 and W2 in accordance with the amount of the beam current of the ion beam to suppress charge-up that is caused by the accumulation of positive charges on the processing target surfaces occurring due to ion implantation. For example, the plasma shower device 36 includes a shower tube 36a through which the ion beam passes and a plasma generation unit 36b that supplies electrons into the shower tube 36a. The shower tube 36a has a shape in which an opening width in the vertical direction (y direction) is long and an opening width in the horizontal direction (x3 direction) is short.

The beam stopper 38 is provided at the most downstream of the beamline A, and is attached to, for example, a side wall of the implantation processing chamber 14. In a case where the workpieces W1 and W2 are not present in the beamline A, the ion beam is incident on the beam stopper 38. The beam stopper 38 is provided with a plurality of tuning cups 38a, 38b, 38c, and 38d. The plurality of tuning cups 38a to 38d are Faraday cups that are configured to measure the beam current of the ion beam incident on the beam stopper 38. The plurality of tuning cups 38a to 38d are arranged, for example, at intervals in the vertical direction (y direction).

The first holding device 40 is configured to hold the first workpiece W1 to be subjected to the implantation processing. The first holding device 40 is configured to reciprocate the first workpiece W1, which is held by the first holding device 40, in a direction crossing the scanning beam. The first holding device 40 is configured to reciprocate the first workpiece W1 in the horizontal direction (x3 direction). The first holding device 40 is movable along guide rails 44 extending in the horizontal direction (x3 direction).

The first holding device 40 includes a first chuck mechanism 50, a first twist mechanism 52, a first vertical angle adjustment mechanism 54, a first horizontal angle adjustment mechanism 56, and a first reciprocating mechanism 58.

The first chuck mechanism 50 is configured to hold the first workpiece W1 in contact with a back surface of the first workpiece W1. The first chuck mechanism 50 includes, for example, an electrostatic chuck for holding the first workpiece W1. The first chuck mechanism 50 may include a temperature control mechanism for cooling or heating the first workpiece W1. The first chuck mechanism 50 includes a first lift mechanism for lifting the first workpiece W1 so that the first workpiece W1 is separated from the first chuck mechanism 50.

The first twist mechanism 52 supports the first chuck mechanism 50 such that the first chuck mechanism 50 is pivotable. The first twist mechanism 52 rotates the first chuck mechanism 50 about a rotation axis (also referred to as a twist axis), which extends in a normal direction of the processing target surface of the first workpiece W1 held by the first chuck mechanism 50, to adjust a twist angle φa1 of the first workpiece W1. For example, the first twist mechanism 52 adjusts the twist angle φa1 between an alignment mark provided on an outer peripheral portion of the first workpiece W1 and a reference position. Here, the alignment mark of the first workpiece W1 refers to, for example, a notch or an orientation flat that is provided on an outer peripheral portion of a wafer, and refers to a mark serving as a reference for an angular position in a crystal axis direction or a circumferential direction of the wafer.

The first vertical angle adjustment mechanism 54 supports the first twist mechanism 52 such that the first twist mechanism 52 is pivotable. The first vertical angle adjustment mechanism 54 rotates the first twist mechanism 52 about a rotation axis (also referred to as a transport tilt axis), which extends in the horizontal direction, to adjust an orientation of the first workpiece W1 in the vertical direction. The orientation of the first workpiece W1 in the vertical direction can be defined by a vertical pivot angle φb1 around the rotation axis extending in the horizontal direction.

The first horizontal angle adjustment mechanism 56 supports the first vertical angle adjustment mechanism 54 such that the first vertical angle adjustment mechanism 54 is pivotable. The first horizontal angle adjustment mechanism 56 rotates the first vertical angle adjustment mechanism 54 about a rotation axis (also referred to as an implantation tilt axis), which extends in the vertical direction, to adjust an orientation of the first workpiece W1 in the horizontal direction. The orientation of the first workpiece W1 in the horizontal direction can be defined by a horizontal pivot angle φc1 around the rotation axis extending in the vertical direction.

The first reciprocating mechanism 58 is configured to move the first horizontal angle adjustment mechanism 56 in the horizontal direction (x3 direction). The first reciprocating mechanism 58 moves the first horizontal angle adjustment mechanism 56 along the guide rails 44. For example, the first reciprocating mechanism 58 includes a first ball screw 58a that extends in the horizontal direction (x3 direction) along the guide rails 44. The first reciprocating mechanism 58 rotates the first ball screw 58a to linearly move the first horizontal angle adjustment mechanism 56 in the horizontal direction.

The second holding device 42 is configured to hold the second workpiece W2 to be subjected to the implantation processing. The second holding device 42 is configured to reciprocate the second workpiece W2, which is held by the second holding device 42, in a direction crossing the scanning beam. The second holding device 42 is configured to reciprocate the second workpiece W2 in the horizontal direction (x3 direction). The second holding device 42 is movable along the guide rails 44 extending in the horizontal direction (x3 direction).

The second holding device 42 can have the same configuration as the first holding device 40. The second holding device 42 is movable in the same direction as the first holding device 40. The second holding device 42 is movable along the guide rails 44 common to the first holding device 40. The second holding device 42 may be configured to be movable along guide rails different from the guide rails for the first holding device 40. That is, the implantation processing chamber 14 may be provided with first guide rails used to move the first holding device 40 and second guide rails used to move the second holding device 42. The second holding device 42 is movable simultaneously with the first holding device 40. The second holding device 42 is movable independently of the first holding device 40.

The second holding device 42 includes a second chuck mechanism 60, a second twist mechanism 62, a second vertical angle adjustment mechanism 64, a second horizontal angle adjustment mechanism 66, and a second reciprocating mechanism 68.

The second chuck mechanism 60 is configured to hold the second workpiece W2 in contact with a back surface of the second workpiece W2. The second chuck mechanism 60 includes, for example, an electrostatic chuck for holding the second workpiece W2. The second chuck mechanism 60 may include a temperature control mechanism for cooling or heating the second workpiece W2. The second chuck mechanism 60 includes a second lift mechanism for lifting the second workpiece W2 so that the second workpiece W2 is separated from the second chuck mechanism 60.

The second twist mechanism 62 supports the second chuck mechanism 60 such that the second chuck mechanism 60 is pivotable. The second twist mechanism 62 rotates the second chuck mechanism 60 about a rotation axis (also referred to as a twist axis), which extends in a normal direction of the processing target surface of the second workpiece W2 held by the second chuck mechanism 60, to adjust a twist angle φa2 of the second workpiece W2. For example, the second twist mechanism 62 adjusts the twist angle φa2 between an alignment mark provided on an outer peripheral portion of the second workpiece W2 and a reference position.

The second vertical angle adjustment mechanism 64 supports the second twist mechanism 62 such that the second twist mechanism 62 is pivotable. The second vertical angle adjustment mechanism 64 rotates the second twist mechanism 62 about a rotation axis (also referred to as a transport tilt axis), which extends in the horizontal direction, to adjust an orientation of the second workpiece W2 in the vertical direction. The orientation of the second workpiece W2 in the vertical direction can be defined by a vertical pivot angle φb2 around the rotation axis extending in the horizontal direction.

The second horizontal angle adjustment mechanism 66 supports the second vertical angle adjustment mechanism 64 such that the second vertical angle adjustment mechanism 64 is pivotable. The second horizontal angle adjustment mechanism 66 rotates the second vertical angle adjustment mechanism 64 about a rotation axis (also referred to as an implantation tilt axis), which extends in the vertical direction, to adjust an orientation of the second workpiece W2 in the horizontal direction. The orientation of the second workpiece W2 in the horizontal direction can be defined by a horizontal pivot angle φc2 around the rotation axis extending in the vertical direction.

The second reciprocating mechanism 68 is configured to move the second horizontal angle adjustment mechanism 66 in the horizontal direction (x3 direction). The second reciprocating mechanism 68 moves the second horizontal angle adjustment mechanism 66 along the guide rails 44. For example, the second reciprocating mechanism 68 includes a second ball screw 68a that extends in the horizontal direction (x3 direction) along the guide rails 44, and rotates the second ball screw 68a to linearly move the second horizontal angle adjustment mechanism 66 in the horizontal direction.

The transport device 16 includes a first transport device 70 and a second transport device 72. The first transport device 70 and the second transport device 72 are disposed away from the beamline A in the horizontal direction (x3 direction). In the example shown in FIG. 1, the first transport device 70 is disposed away from the beamline A in the −x3 direction, and the second transport device 72 is disposed away from the beamline A in the +x3 direction. For example, the first transport device 70 and the second transport device 72 are disposed such that the beam stopper 38 is positioned between the first transport device 70 and the second transport device 72.

The first transport device 70 is configured to transport the first workpiece W1, which is not yet subjected to the implantation processing, into the implantation processing chamber 14 and to transport the first workpiece W1, which has been subjected to the implantation processing, out of the implantation processing chamber 14. The first transport device 70 transports the first workpiece W1 onto the first holding device 40 and transports the first workpiece W1 out of the first holding device 40. For example, the first transport device 70 includes a first transport robot (not shown) for transporting the first workpiece W1. The first transport device 70 transports the first workpiece W1 through a first transport port 74 provided in the side wall of the implantation processing chamber 14.

The second transport device 72 is configured to transport the second workpiece W2, which is not yet subjected to the implantation processing, into the implantation processing chamber 14 and to transport the second workpiece W2, which has been subjected to the implantation processing, out of the implantation processing chamber 14. The second transport device 72 transports the second workpiece W2 onto the second holding device 42 and transports the second workpiece W2 out of the second holding device 42. For example, the second transport device 72 includes a second transport robot (not shown) for transporting the second workpiece W2. The second transport device 72 transports the second workpiece W2 through a second transport port 76 provided in the side wall of the implantation processing chamber 14.

The control device 18 controls the overall operation of the ion implanter 10. The control device 18 is realized by elements, such as a CPU and a memory of a computer, or a mechanical device in terms of hardware, and is realized by a computer program in terms of software. Various functions provided by the control device 18 can be realized by the cooperation of the hardware and the software.

The control device 18 includes a processor 18a such as a central processing unit (CPU) and a memory 18b such as a read-only memory (ROM) or a random-access memory (RAM). For example, the control device 18 causes the processor 18a to execute a program stored in the memory 18b to control the overall operation of the ion implanter 10 in accordance with the program. The processor 18a may execute a program stored in any storage device different from the memory 18b, may execute a program acquired from any recording medium by a reading device, or may execute a program acquired via a network. The memory 18b storing the program may be a volatile memory such as a dynamic random access memory (DRAM), or may be a non-volatile memory such as an electrically erasable programmable read-only memory (EEPROM), a flash memory, a magnetoresistive random access memory, a resistive random access memory, or a ferroelectric memory. A non-volatile memory, a magnetic storage medium such as a magnetic tape and a magnetic disk, and an optical storage medium such as an optical disk are examples of a non-transitory and tangible computer readable storage medium.

Various functions provided by the control device 18 may be realized by a single device including the processor 18a and the memory 18b, or may be realized by the cooperation of a plurality of devices, each of which includes the processor 18a and the memory 18b.

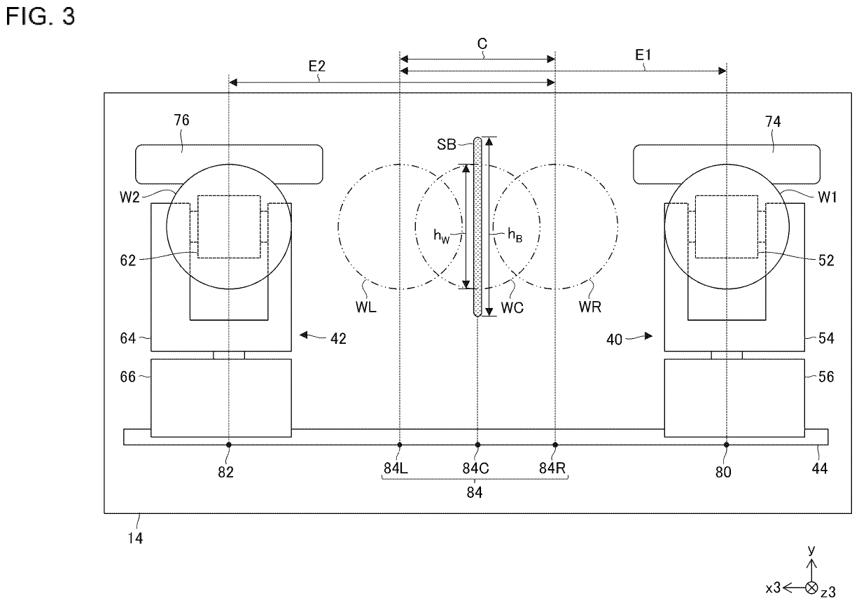

FIG. 3 is a front view showing a schematic configuration of the first holding device 40 and the second holding device 42, and shows a configuration as viewed in a beam traveling direction (z3 direction) in the implantation processing chamber 14. In FIG. 3, the first holding device 40 is disposed at a first transport position 80 and the second holding device 42 is disposed at a second transport position 82. The first transport position 80 is a position at which the first workpiece W1 is transported onto the first holding device 40 or out of the first holding device 40 through the first transport port 74. The first transport position 80 corresponds to the position of the first transport port 74. The second transport position 82 is a position at which the second workpiece W2 is transported onto the second holding device 42 or out of the second holding device 42 through the second transport port 76. The second transport position 82 corresponds to the position of the second transport port 76. The first transport position 80 and the second transport position 82 are away from an implantation position 84, at which the workpieces W1 and W2 are irradiated with the ion beam, in the horizontal direction (x3 direction).

The implantation position 84 is located in a middle portion of the implantation processing chamber 14 in the horizontal direction (x3 direction). The implantation position 84 is located between the first transport position 80 and the second transport position 82. The implantation position 84 includes an implantation center position 84C, an implantation left end position 84L, and an implantation right end position 84R. In FIG. 3, workpieces WC, WL, and WR positioned at the implantation center position 84C, the implantation left end position 84L, and the implantation right end position 84R, respectively, are shown by a two-dot chain line. The implantation center position 84C corresponds to a position where the scanning beam SB generated by the beam generation device 12 is applied. The implantation left end position 84L is a position that is shifted to a left side (the +x3 direction in FIG. 3) from the implantation center position 84C, and is set such that the entire processing target surface of the workpiece WL disposed at the implantation left end position 84L does not overlap with the scanning beam SB. The implantation right end position 84R is a position that is shifted to a right side (the −x3 direction in FIG. 3) from the implantation center position 84C, and is set such that the entire processing target surface of the workpiece WR disposed at the implantation right end position 84R does not overlap with the scanning beam SB.

The size h_{B} of an irradiation range, which is irradiated with the scanning beam SB, in the vertical direction (y direction) is larger than the size h_{w} of each of the processing target surfaces of the workpieces W1 and W2 in the vertical direction (y direction). The size h_{B} of the irradiation range, which is irradiated with the scanning beam SB, in the vertical direction is, for example, 1.1 times or more and 3 times or less the size h_{w} of each of the processing target surfaces of the workpieces W1 and W2 in the vertical direction, and is preferably 1.2 times or more and 2 times or less the size h_{w}.

The first holding device 40 reciprocates in the horizontal direction (x3 direction) at the implantation position 84, so that the entire processing target surface of the first workpiece W1 is irradiated with the scanning beam SB. The first holding device 40 reciprocates in a movement range C from the implantation left end position 84L to the implantation right end position 84R, so that the entire processing target surface of the first workpiece W1 is irradiated with the scanning beam SB. The first holding device 40 is moved to the first transport position 80, so that the first workpiece W1 can be transported in or out. The first holding device 40 is movable between the implantation position 84 and the first transport position 80. The first holding device 40 is movable over a first movable range E1 from the first transport position 80 to the implantation left end position 84L. The first holding device 40 is immovable to the second transport position 82.

The second holding device 42 reciprocates in the horizontal direction (x3 direction) at the implantation position 84, so that the entire processing target surface of the second workpiece W2 is irradiated with the scanning beam SB. The second holding device 42 reciprocates in the movement range C from the implantation left end position 84L to the implantation right end position 84R, so that the entire processing target surface of the second workpiece W2 is irradiated with the scanning beam SB. The second holding device 42 is moved to the second transport position 82, so that the second workpiece W2 can be transported in or out. The second holding device 42 is movable between the implantation position 84 and the second transport position 82. The second holding device 42 is movable over a second movable range E2 from the second transport position 82 to the implantation right end position 84R. The second holding device 42 is immovable to the first transport position 80.

A first implantation position at which the first workpiece W1 held by the first holding device 40 is irradiated with the ion beam is common to a second implantation position at which the second workpiece W2 held by the second holding device 42 is irradiated with the ion beam. That is, the first implantation position and the second implantation position coincide with the common implantation position 84. Further, a first movement range in which the first holding device 40 reciprocates the first workpiece W1 at the first implantation position is common to a second movement range in which the second holding device 42 reciprocates the second workpiece W2 at the second implantation position. That is, the first movement range and the second movement range coincide with the common movement range C. The first movement range and the second movement range overlap with each other as viewed in the beam traveling direction. The position of the first workpiece W1, which is held by the first holding device 40 at the first implantation position, in the vertical direction is common to the position of the second workpiece W2, which is held by the second holding device 42 at the second implantation position, in the vertical direction. The position of the first workpiece W1, which is held by the first holding device 40 at the first implantation position, in the beam traveling direction is common to the position of the second workpiece W2, which is held by the second holding device 42 at the second implantation position, in the beam traveling direction. Accordingly, the first holding device 40 and the second holding device 42 are configured to be capable of reciprocating the first workpiece W1 and the second workpiece W2 in the same manner with respect to the scanning beam SB. Therefore, the first workpiece W1 and the second workpiece W2 are irradiated with the scanning beam SB in a common implantation environment.

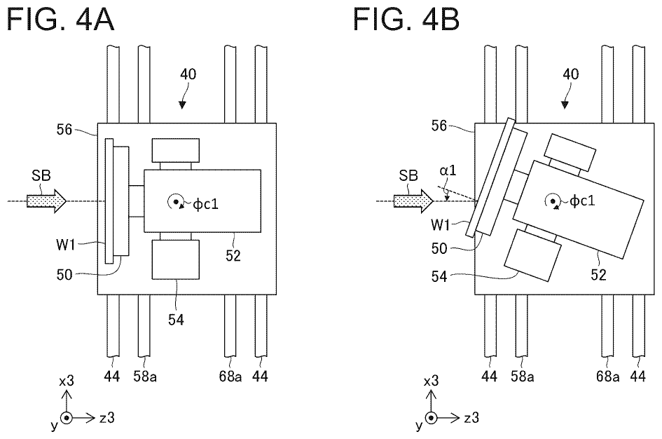

FIGS. 4A and 4B are top views schematically showing the orientation of the first workpiece W1, which is held by the first holding device 40, in the horizontal direction. FIGS. 4A and 4B show a change in the orientation of the first workpiece W1, which is adjusted by the first horizontal angle adjustment mechanism 56, in the horizontal direction. The same applies to the orientation of the second workpiece W2, which is held by the second holding device 42, in the horizontal direction.

FIGS. 4A and 4B show the orientation of the first workpiece W1 in an implantation process in which the first workpiece W1 is irradiated with the scanning beam SB. FIG. 4A shows a case where the processing target surface of the first workpiece W1 is perpendicular to the traveling direction (z3 direction) of the scanning beam SB. FIG. 4B shows a case where the processing target surface of the first workpiece W1 obliquely intersects with the traveling direction (z3 direction) of the scanning beam SB. In FIG. 4B, the processing target surface of the first workpiece W1 has a horizontal tilt angle α1 with respect to the traveling direction (z3 direction) of the scanning beam SB. The horizontal tilt angle α1 indicates a horizontal inclination of the incident direction of the scanning beam SB with respect to a normal to the processing target surface of the first workpiece W1. The first holding device 40 can adjust the horizontal tilt angle α1 of the first workpiece W1 by driving the first horizontal angle adjustment mechanism 56 to adjust the horizontal pivot angle φc1. The first holding device 40 is configured to be capable of adjusting the horizontal tilt angle α1 within, for example, a range of ±30 degrees or a range of ±60 degrees during ion implantation.

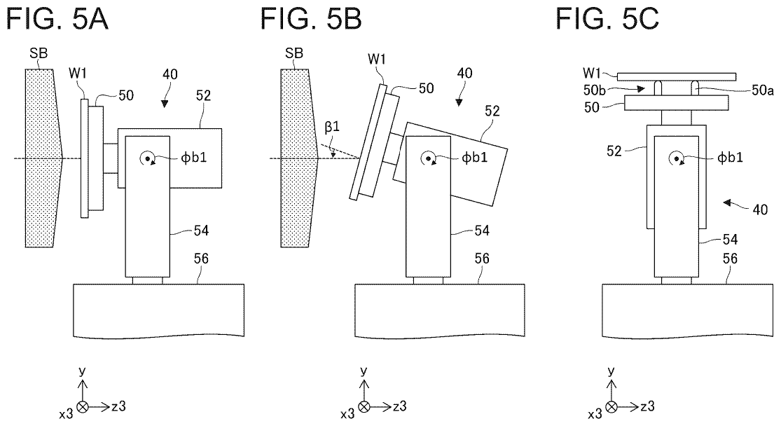

FIGS. 5A to 5C are side views schematically showing the orientation of the first workpiece W1, which is held by the first holding device 40, in the vertical direction. FIGS. 5A to 5C show a change in the orientation of the first workpiece W1, which is adjusted by the first vertical angle adjustment mechanism 54, in the vertical direction. The same applies to the orientation of the second workpiece W2, which is held by the second holding device 42, in the vertical direction.

FIG. 5A shows an example of the orientation of the first workpiece W1 in the implantation process in which the first workpiece W1 is irradiated with the scanning beam SB. In FIG. 5A, the first holding device 40 holds the first workpiece W1 such that the processing target surface of the first workpiece W1 is oriented in a direction perpendicular to the traveling direction (z3 direction) of the scanning beam SB. That is, the first holding device 40 holds the first workpiece W1 in an orientation in which the processing target surface of the first workpiece W1 is not along the horizontal direction. In the example shown in FIG. 5A, the first holding device 40 holds the first workpiece W1 in an orientation in which the processing target surface of the first workpiece W1 is along the vertical direction.

FIG. 5B shows another example of the orientation of the first workpiece W1 in the implantation process in which the first workpiece W1 is irradiated with the scanning beam SB. In FIG. 5B, the first holding device 40 holds the first workpiece W1 in an orientation in which the processing target surface of the first workpiece W1 is inclined with respect to the vertical direction. In FIG. 5B, the first holding device 40 holds the first workpiece W1 in an orientation in which the processing target surface of the first workpiece W1 is not along the horizontal direction. In FIG. 5B, the processing target surface of the first workpiece W1 has a vertical tilt angle β1 with respect to the traveling direction (z3 direction) of the scanning beam SB. The vertical tilt angle β1 indicates a vertical inclination of the incident direction of the scanning beam SB with respect to the normal to the processing target surface of the first workpiece W1. The first holding device 40 can adjust the vertical tilt angle β1 by driving the first vertical angle adjustment mechanism 54 to adjust the vertical pivot angle φb1. The first holding device 40 is configured to be capable of adjusting the vertical tilt angle β1 within, for example, a range of ±30 degrees or a range of ±60 degrees during ion implantation.

FIG. 5C shows the orientation of the first workpiece W1 in a transport process of transporting the first workpiece W1 onto the first holding device 40 or out of the first holding device 40. In FIG. 5C, the first holding device 40 holds the first workpiece W1 in an orientation in which the processing target surface of the first workpiece W1 is along the horizontal direction. In FIG. 5C, the first holding device 40 lifts the first workpiece W1 using the first lift mechanism 50a so that the first workpiece W1 is separated from the first chuck mechanism 50. Accordingly, an arm of the first transport robot for transporting the first workpiece W1 in or out can be inserted into a gap 50b between the first chuck mechanism 50 and the first workpiece W1. It is not essential that the arm of the first transport robot is inserted into the gap 50b between the first chuck mechanism 50 and the first workpiece W1. The arm of the first transport robot may be configured to support the outer peripheral portion of the first workpiece W1 instead of the back surface of the first workpiece W1. In this case, the gap 50b may be very small.

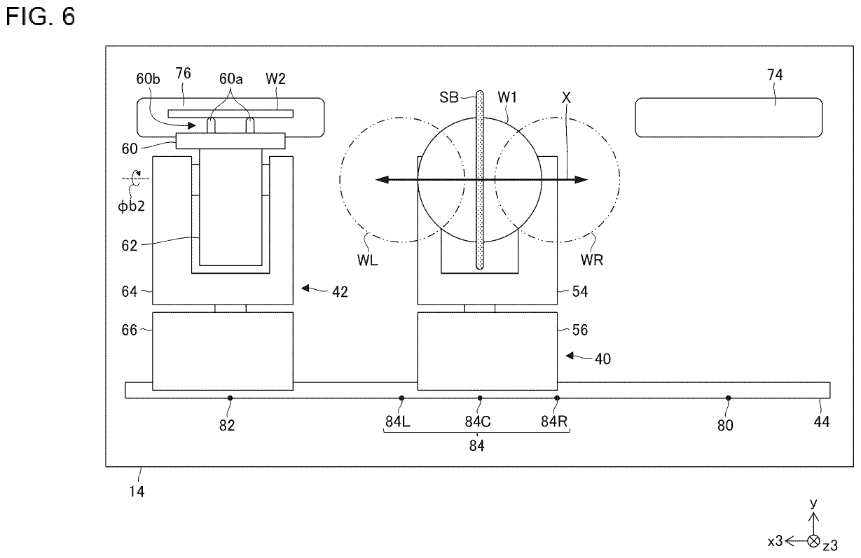

FIGS. 6 to 9 are front views showing an example of the operation of the first holding device 40 and the second holding device 42. FIG. 6 shows a situation in which a first implantation process is performed on the first workpiece W1. In FIG. 6, the first holding device 40 is disposed at the implantation position 84 and the second holding device 42 is disposed at the second transport position 82. The first holding device 40 reciprocates in the horizontal direction at the implantation position 84 as shown by an arrow X, for the implantation processing to be executed on the first workpiece W1. The second holding device 42 lifts the second workpiece W2 at the second transport position 82 using the second lift mechanism 60a, in order to transport the second workpiece W2, which has been subjected to the implantation processing, out through the second transport port 76. The second holding device 42 receives the second workpiece W2 at the second transport position 82 using the second lift mechanism 60a, in order to transport the second workpiece W2, which is not yet subjected to the implantation processing, in through the second transport port 76.

In FIG. 6, the first holding device 40 holds the first workpiece W1 such that the processing target surface of the first workpiece W1 is oriented to be irradiated with the scanning beam SB. For example, the first holding device 40 holds the first workpiece W1 in an orientation in which the horizontal tilt angle α1 is 0 as shown in FIG. 4A. For example, the first holding device 40 holds the first workpiece W1 in an orientation in which the vertical tilt angle β1 is 0 as shown in FIG. 5A. The first holding device 40 may hold the first workpiece W1 in an orientation in which the horizontal tilt angle α1 is not 0 as shown in FIG. 4B. The first holding device 40 may hold the first workpiece W1 in an orientation in which the vertical tilt angle β1 is not 0 as shown in FIG. 5B. The first holding device 40 may hold the first workpiece W1 in an orientation in which both the horizontal tilt angle α1 and the vertical tilt angle β1 are not 0.

In FIG. 6, the second holding device 42 holds the second workpiece W2 such that the second workpiece W2 is oriented to be capable of being transported in or out through the second transport port 76. The second holding device 42 holds the second workpiece W2 in an orientation in which the processing target surface of the second workpiece W2 is along the horizontal direction in the same manner as FIG. 5C. The second holding device 42 lifts the second workpiece W2 using the second lift mechanism 60a to form a gap 60b between the second chuck mechanism 60 and the second workpiece W2. The second transport device 72 inserts an arm of the second transport robot into the gap 60b between the second chuck mechanism 60 and the second workpiece W2 to transport the second workpiece W2, which has been subjected to the implantation processing, out. In a case where the second workpiece W2 not yet subjected to the implantation processing is placed on the second lift mechanism 60a by the arm of the second transport robot, the second holding device 42 releases the lift of the second workpiece W2 and holds the second workpiece W2 on the second chuck mechanism 60. After holding the second workpiece W2 not yet subjected to the implantation processing, the second holding device 42 drives the second vertical angle adjustment mechanism 64 to change the vertical pivot angle φb2 and holds the second workpiece W2 in an orientation in which the processing target surface of the second workpiece W2 is not along the horizontal direction.

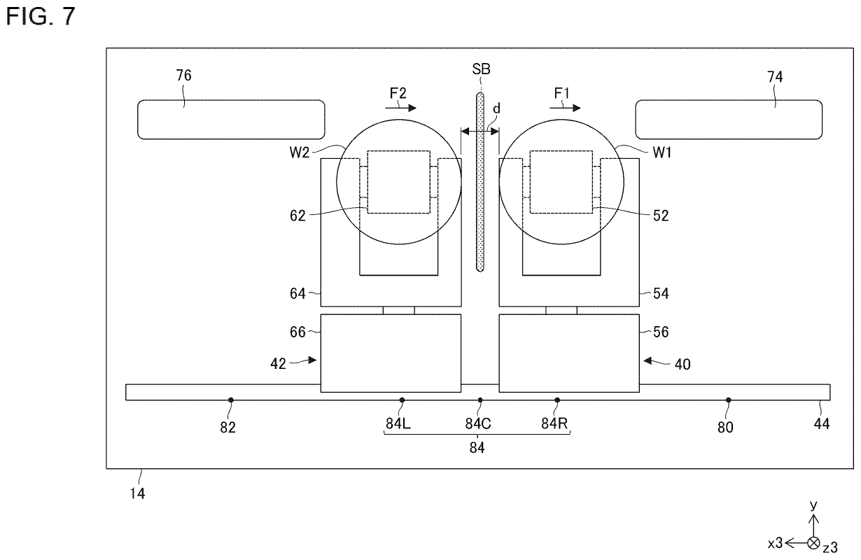

FIG. 7 shows a situation in which the first implantation process to be executed on the first workpiece W1 is switched to a second implantation process to be executed on the second workpiece W2. That is, FIG. 7 shows a situation in which the first implantation process to be executed on the first workpiece W1 ends and the second implantation process to be executed on the second workpiece W2 starts. In FIG. 7, the first holding device 40 is moved from the implantation position 84 toward the first transport position 80 as shown by an arrow F1, and the second holding device 42 is moved from the second transport position 82 toward the implantation position 84 as shown by an arrow F2. Since the first holding device 40 and the second holding device 42 are moved simultaneously in the same direction as shown in FIG. 7, a time required to switch from the first implantation process to the second implantation process can be shortened.

In FIG. 7, the first holding device 40 and the second holding device 42 can be moved such that a relative distance d between the first workpiece W1 held by the first holding device 40 and the second workpiece W2 held by the second holding device 42 is maintained. For example, in a case where the movement speeds of the first holding device 40 and the second holding device 42 are set to the same speed, the relative distance d can be maintained constant. The movement speeds of the first holding device 40 and the second holding device 42 may be adjusted to move the first holding device 40 and the second holding device 42 such that the relative distance d is maintained within a range from a predetermined upper limit to a predetermined lower limit. In this case, the movement speed of the first holding device 40 may be set to be higher or lower than the movement speed of the second holding device 42. In a case of ion implantation in which a uniform dose distribution is to be applied to the workpiece in the horizontal direction, it is preferable that the relative distance d is as short as possible. In a case of ion implantation in which a non-uniform dose distribution is to be applied to the workpiece in the horizontal direction, it is preferable that the relative distance d is larger than the size of the scanning beam SB in the horizontal direction (x3 direction).

In FIG. 7, the movement speed of the first holding device 40 that holds the first workpiece W1 on which the implantation process ends may be the maximum speed of the first holding device 40. In a case where the first holding device 40 is moved at the maximum speed, a time from the completion of the first implantation process on the first workpiece W1 to the transport-out of the first workpiece W1 can be shortened. As a result, productivity can be improved. On the other hand, the movement speed of the second holding device 42 that holds the second workpiece W2 on which the implantation process starts may be determined in accordance with implantation conditions of the second workpiece W2. In a case where the second holding device 42 is moved at a movement speed corresponding to the implantation conditions, the second workpiece W2 is moved to the implantation position 84 and then the second implantation process to be executed on the second workpiece W2 can start at the same movement speed. Accordingly, the start of the second implantation process can be accelerated, so that productivity can be improved.

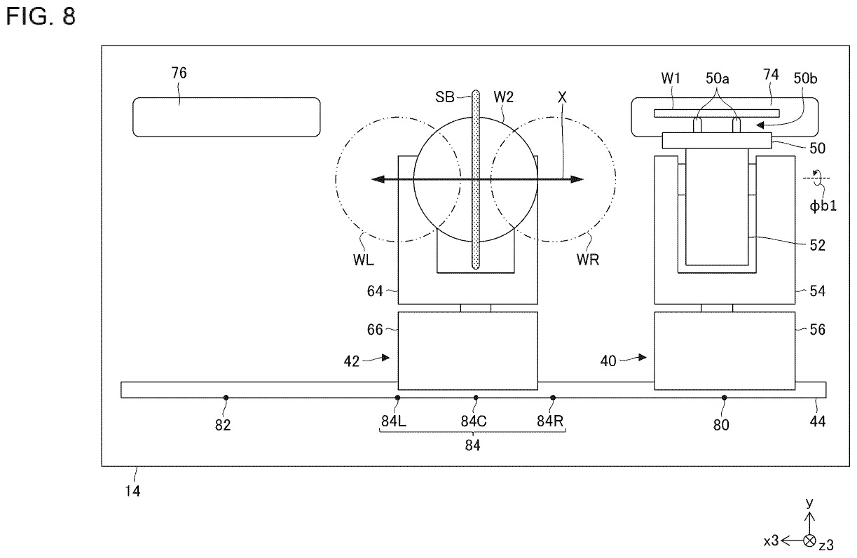

FIG. 8 shows a situation in which the second implantation process is performed on the second workpiece W2. In FIG. 8, the second holding device 42 is disposed at the implantation position 84 and the first holding device 40 is disposed at the first transport position 80. The second holding device 42 reciprocates in the horizontal direction at the implantation position 84 as shown by an arrow X, for the implantation processing to be executed on the second workpiece W2. The first holding device 40 lifts the first workpiece W1 at the first transport position 80 using the first lift mechanism 50a, in order to transport the first workpiece W1, which has been subjected to the implantation processing, out through the first transport port 74. The first holding device 40 receives the first workpiece W1 at the first transport position 80 using the first lift mechanism 50a, in order to transport the first workpiece W1, which is not yet subjected to the implantation processing, in through the first transport port 74.

In FIG. 8, the second holding device 42 holds the second workpiece W2 such that the processing target surface of the second workpiece W2 is oriented to be irradiated with the scanning beam SB. For example, the second holding device 42 holds the second workpiece W2 in an orientation in which a horizontal tilt angle α2 is 0 in the same manner as FIG. 4A. For example, the second holding device 42 holds the second workpiece W2 in an orientation in which a vertical tilt angle β2 is 0 in the same manner as FIG. 5A. The second holding device 42 may hold the second workpiece W2 in an orientation in which the horizontal tilt angle α2 is not 0 in the same manner as FIG. 4B. The second holding device 42 may hold the second workpiece W2 in an orientation in which the vertical tilt angle β2 is not 0 in the same manner as FIG. 5B. The second holding device 42 may hold the second workpiece W2 in an orientation in which both the horizontal tilt angle α2 and the vertical tilt angle β2 are not 0.

In FIG. 8, the first holding device 40 holds the first workpiece W1 such that the first workpiece W1 is oriented to be capable of being transported in or out through the first transport port 74. The first holding device 40 holds the first workpiece W1 such that the processing target surface of the first workpiece W1 is oriented along the horizontal direction as shown in FIG. 5C. The first holding device 40 lifts the first workpiece W1 using the first lift mechanism 50a to form a gap 50b between the first chuck mechanism 50 and the first workpiece W1. The first transport device 70 inserts the arm of the first transport robot into the gap 50b between the first chuck mechanism 50 and the first workpiece W1 to transport the first workpiece W1, which has been subjected to the implantation processing, out. In a case where the first workpiece W1 not yet subjected to the implantation processing is placed on the first lift mechanism 50a by the arm of the first transport robot, the first holding device 40 releases the lift of the first workpiece W1 and holds the first workpiece W1 on the first chuck mechanism 50. After holding the first workpiece W1 not yet subjected to the implantation processing, the first holding device 40 drives the first vertical angle adjustment mechanism 54 to change the vertical pivot angle φb1 and holds the first workpiece W1 in an orientation in which the processing target surface of the first workpiece W1 is not along the horizontal direction.

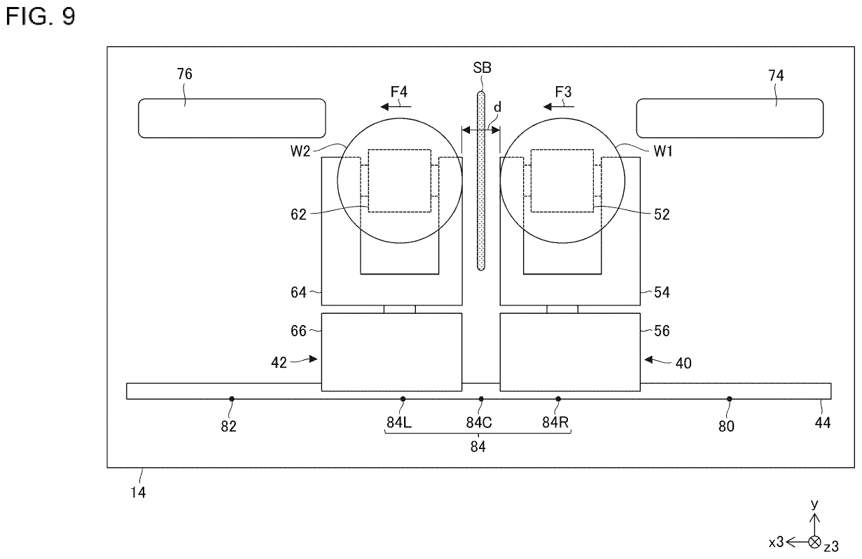

FIG. 9 shows a situation in which the second implantation process to be executed on the second workpiece W2 is switched to the first implantation process to be executed on the first workpiece W1. That is, FIG. 9 shows a situation in which the second implantation process to be executed on the second workpiece W2 ends and the first implantation process to be executed on the first workpiece W1 starts. In FIG. 9, the first holding device 40 is moved from the first transport position 80 toward the implantation position 84 as shown by an arrow F3, and the second holding device 42 is moved from the implantation position 84 toward the second transport position 82 as shown by an arrow F4. Since the first holding device 40 and the second holding device 42 are moved simultaneously in the same direction as shown in FIG. 9, a time required to switch from the second implantation process to the first implantation process can be shortened.

In FIG. 9, the first holding device 40 and the second holding device 42 can be moved such that a relative distance d between the first workpiece W1 held by the first holding device 40 and the second workpiece W2 held by the second holding device 42 is maintained. For example, in a case where the movement speeds of the first holding device 40 and the second holding device 42 are set to the same speed, the relative distance d can be maintained constant. The movement speeds of the first holding device 40 and the second holding device 42 may be adjusted to move the first holding device 40 and the second holding device 42 such that the relative distance d is maintained within a range from a predetermined upper limit to a predetermined lower limit. In this case, the movement speed of the first holding device 40 may be set to be higher or lower than the movement speed of the second holding device 42. It is preferable that the relative distance d is larger than the size of the scanning beam SB in the horizontal direction (x3 direction).

In FIG. 9, the movement speed of the second holding device 42 that holds the second workpiece W2 on which the implantation process ends may be the maximum speed of the second holding device 42. In a case where the second holding device 42 is moved at the maximum speed, a time from the completion of the second implantation process on the second workpiece W2 to the transport-out of the second workpiece W2 can be shortened. As a result, productivity can be improved. On the other hand, the movement speed of the first holding device 40 that holds the first workpiece W1 on which the implantation process starts may be determined in accordance with implantation conditions of the first workpiece W1. In a case where the first holding device 40 is moved at a movement speed corresponding to the implantation conditions, the first workpiece W1 is moved to the implantation position 84 and then the first implantation process to be executed on the first workpiece W1 can start at the same movement speed. Accordingly, the start of the first implantation process can be accelerated, so that productivity can be improved.

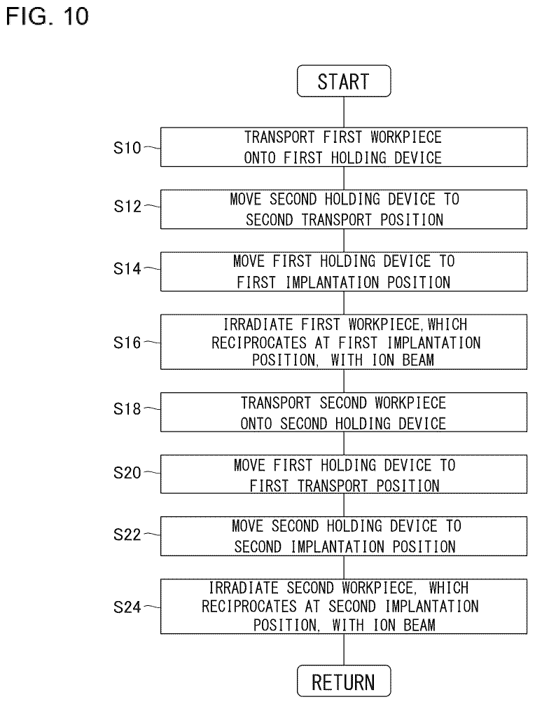

FIG. 10 is a flowchart showing a flow of an ion implantation method according to an embodiment. First, the first workpiece W1 not yet subjected to the implantation processing is transported onto the first holding device 40 (S10). In S10, after the first workpiece W1, which has been subjected to the implantation processing and is held by the first holding device 40, is transported out, a first workpiece W1 not yet subjected to the implantation processing may be transported onto the first holding device 40. Next, the second holding device 42 is moved to the second transport position 82 (S12), and the first holding device 40 is moved to the first implantation position (for example, the implantation position 84) (S14). S12 and S14 can be executed simultaneously, or can be executed such that the respective execution periods of S12 and S14 overlap with each other at least partially. Subsequently, the first holding device 40 is reciprocated at the first implantation position, so that the first workpiece W1, which reciprocates, is irradiated with the ion beam (S16).

Before, during, or after the execution of S16, a second workpiece W2 not yet subjected to the implantation processing is transported onto the second holding device 42 (S18). In S18, after the second workpiece W2, which has been subjected to the implantation processing and is held by the second holding device 42, is transported out, a second workpiece W2 not yet subjected to the implantation processing may be transported onto the second holding device 42. Next, the first holding device 40 is moved to the first transport position 80 (S20), and the second holding device 42 is moved to the second implantation position (for example, the implantation position 84) (S22). S20 and S22 can be executed simultaneously, or can be executed such that the respective execution periods of S20 and S22 overlap with each other at least partially. Subsequently, the second holding device 42 is reciprocated at the second implantation position, so that the second workpiece W2, which reciprocates, is irradiated with the ion beam (S24).

The flow shown in FIG. 10 can be repeatedly executed. For example, the processing of S10 to be executed after the repetition can be executed before, during, or after the execution of S24. Before, during, or after the execution of S24, the first workpiece W1, which has been subjected to the implantation processing and is held by the first holding device 40, can be transported out, and the first workpiece W1 not yet subjected to the implantation processing can be transported onto the first holding device 40. In a case where the flow shown in FIG. 10 is repeated, the first implantation process to be executed on the first workpiece W1 held by the first holding device 40 and the second implantation process to be executed on the second workpiece W2 held by the second holding device 42 can be alternately repeated. The flow shown in FIG. 10 can be repeatedly executed until implantation processes for a plurality of workpieces to be continuously processed are completed.

According to the present embodiment, the plurality of holding devices are provided in the implantation processing chamber 14. Accordingly, the implantation process and the transport process for workpieces can be executed in parallel. For example, the transport process of the second workpiece W2 can be executed by the second holding device 42 simultaneously with the first implantation process to be executed on the first workpiece W1 held by the first holding device 40. Further, the transport process of the first workpiece W1 can be executed by the first holding device 40 simultaneously with the second implantation process to be executed on the second workpiece W2 held by the second holding device 42. As a result, as compared to a case where the implantation process and the transport process are alternately executed using a single holding device, a time required to continuously process a plurality of workpieces can be shortened and productivity can be improved.

According to the present embodiment, the plurality of holding devices are configured to reciprocate in the horizontal direction. Accordingly, the complexity of the configuration of the implantation processing chamber 14 and the transport device 16 can be suppressed as compared to a configuration in which the plurality of holding devices reciprocate in the vertical direction. Further, since the plurality of holding devices are configured to reciprocate in the horizontal direction, the sizes of the implantation processing chamber 14 and the transport device 16 in the vertical direction can be reduced. As a result, the ion implanter 10 having an external size within a height limit range in a floor of a general semiconductor processing factory can be provided.

According to the present embodiment, the plurality of holding devices are configured to move along the common guide rails 44. Accordingly, the respective reciprocations of the plurality of holding devices at the implantation position can be made common. Therefore, it is possible to prevent a difference in the implantation environment from occurring due to the use of the plurality of holding devices. As a result, it is possible to improve the productivity of the implantation processing to be executed on the plurality of workpieces while suppressing a variation in the implantation processing to be executed on the plurality of workpieces.

According to the present embodiment, reciprocating scanning is performed in the vertical direction with the ion beam and the workpiece is reciprocated in the horizontal direction. Accordingly, the entire processing target surface of the workpiece can be efficiently irradiated with the scanning beam. Further, since the ion beam is deflected in the horizontal direction in the mass spectrometry unit 24 and the energy filter unit 34, the beamline A that travels along the horizontal plane can be formed. Accordingly, the size of the beam generation device 12 in the vertical direction can be reduced.

According to the present embodiment, the front slit 20c of the ion source 20 is formed in the shape of a slit long in the horizontal direction. Accordingly, the ion beam spreading in the horizontal direction can be generated through the extraction unit 22. As a result, it is easy to generate an ion beam having a large beam current as compared to a case where a spot-like ion beam is extracted from the ion source 20. Further, since the size of the ion beam, which is extracted from the ion source 20, in the vertical direction is small, an interval, through which the ion beam passes, between magnetic poles, which face each other, of the mass spectrometry magnet device 24a can be made small. As a result, the size of the mass spectrometry magnet device 24a can be reduced. For example, as compared to a comparative example in which a front slit of the ion source is formed in the shape of a slit narrow in the horizontal direction and long in the vertical direction, it is possible to generate an ion beam having a large beam current while reducing the size of the mass spectrometry magnet device 24a.

According to the present embodiment, the ion beam spreading in the horizontal direction is formed into a spot shape by the beam shaping unit 26. Accordingly, a spot beam suitable for beam scanning in the vertical direction, which is performed by the beam scanning unit 28, can be formed. Scanning is performed in the vertical direction with the spot beam by the beam scanning unit 28, so that ions can be implanted into a workpiece having a large size in the vertical direction. According to the present embodiment, a workpiece having a large size in the vertical direction can be irradiated with a scanning beam having a larger beam current. Accordingly, the productivity of the implantation processing can be improved.

In the present embodiment, a direction in which the magnetic field B1 is applied in the ion source 20 and a direction in which the magnetic field B2 is applied in the mass spectrometry unit 24 are perpendicular to each other. Accordingly, there is a high possibility that the quality of the beam and the control of the magnetic field may be adversely affected by interference between both the magnetic field B1 and the magnetic field B2. On the other hand, in the case of the comparative example in which a direction in which a magnetic field is applied in the ion source is the vertical direction, the direction in which a magnetic field is applied in the ion source and a direction in which a magnetic field is applied in the mass spectrometry unit are parallel to each other. Therefore, even if both the magnetic fields interfere with each other to some extent, there is no major problem. According to the present embodiment, the magnetic shield 23 is provided between the extraction unit 22 and the mass spectrometry unit 24. Accordingly, magnetic field interference between the magnetic field B1 that is parallel to the horizontal direction and applied in the ion source 20 and the magnetic field B2 that is parallel to the vertical direction and applied in the mass spectrometry unit 24 can be suppressed. Therefore, it is possible to achieve both high plasma generation efficiency of the ion source 20 and high mass spectrometry accuracy of the mass spectrometry unit 24.

The present embodiment can be applied in the ion implantation processing to be executed on a workpiece having a large size in the vertical direction. An example of the workpiece having a large size in the vertical direction is a large substrate that is used to manufacture a flat panel display (FPD). The sizes of such a large substrate in the vertical direction and the horizontal direction are, for example, 1 m×2 m or more. It is not realistic to reciprocate such a large workpiece in the vertical direction. According to the present embodiment, the workpiece is reciprocated in the horizontal direction. Therefore, it is easy to reciprocate a large substrate as compared to a case where the workpiece is reciprocated in the vertical direction. A large substrate, which reciprocates in the horizontal direction, is irradiated with an ion beam scanning in the vertical direction, so that ion implantation processing can be executed on the large substrate.

In a case where a workpiece is a large substrate for an FPD, the ion implanter 10 may not include at least one of the beam collimation unit 30, the acceleration/deceleration unit 32, and the energy filter unit 34. In a case where a workpiece is a large substrate for an FPD, the workpiece may be moved in the horizontal direction to be transported into the implantation processing chamber 14 and transported out of the implantation processing chamber 14. For example, a large substrate not yet subjected to the implantation processing may be transported into the implantation processing chamber 14 from the right side (or left side) of the implantation processing chamber 14 and may be moved in the leftward direction (or rightward direction) in the implantation processing chamber 14 and be subjected to the ion implantation processing, and the large substrate having been subjected to the implantation processing may be transported out of the implantation processing chamber 14 from the left side (or right side) of the implantation processing chamber 14. Accordingly, the ion implanter 10 may continuously process a large substrate in an in-line manner.

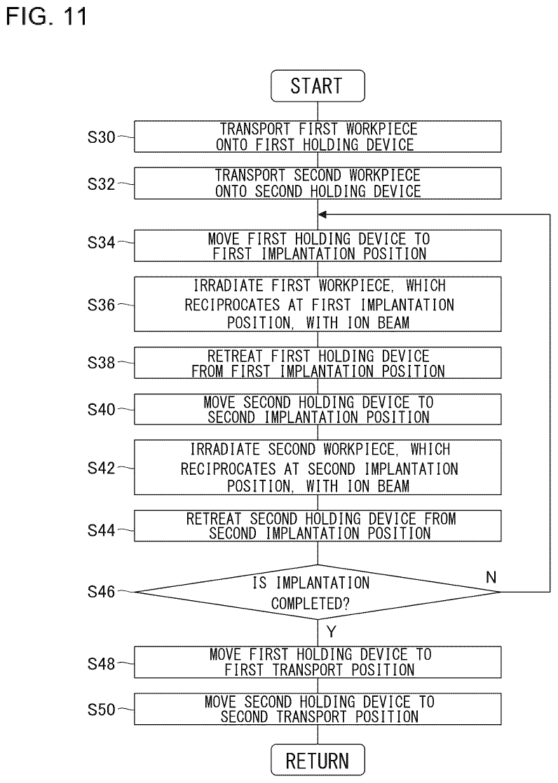

FIG. 11 is a flowchart showing a flow of an ion implantation method according to a modification example. In the flow shown in FIG. 11, a first implantation process to be executed on the first workpiece W1 and a second implantation process to be executed on the second workpiece W2 are executed in parallel.

First, the first workpiece W1 not yet subjected to the implantation processing is transported onto the first holding device 40 (S30). In S30, after the first workpiece W1, which has been subjected to the implantation processing and is held by the first holding device 40, is transported out, a first workpiece W1 not yet subjected to the implantation processing may be transported onto the first holding device 40. Further, a second workpiece W2 not yet subjected to the implantation processing is transported onto the second holding device 42 (S32). In S32, after the second workpiece W2, which has been subjected to the implantation processing and is held by the second holding device 42, is transported out, a second workpiece W2 not yet subjected to the implantation processing may be transported onto the second holding device 42. An order of the processes S30 and S32 is not limited, and S32 may start after the start of S30 or S30 may start after the start of S32. The processes S30 and S32 may be executed simultaneously.

Subsequently, the first holding device 40 is moved to the first implantation position (for example, the implantation position 84) (S34). The first holding device 40 is reciprocated at the first implantation position, so that the first workpiece W1, which reciprocates, is irradiated with the ion beam (S36). The number of reciprocations of the first workpiece W1 in S36 is not particularly limited, and may be, for example, only one. Then, the first holding device 40 is retreated from the first implantation position (S38), and the second holding device 42 is moved to the second implantation position (for example, the implantation position 84) (S40). A first retreat position to which the first holding device 40 is retreated is located, for example, between the first transport position 80 and the first implantation position. The first retreat position to which the first holding device 40 is retreated may be the same as the first transport position 80.

Subsequently, the second holding device 42 is reciprocated at the second implantation position, so that the second workpiece W2, which reciprocates, is irradiated with the ion beam (S42). The number of reciprocations of the second workpiece W2 in S42 is not particularly limited, and may be, for example, only one. Then, the second holding device 42 is retreated from the second implantation position (S44). A second retreat position to which the second holding device 42 is retreated is located, for example, between the second transport position 82 and the second implantation position. The second retreat position to which the second holding device 42 is retreated may be the same as the second transport position 82.

In a case where the implantation processing to be executed on the first workpiece W1 and the second workpiece W2 is not completed (N in S46), the processes S34 to S44 are repeated until the implantation processing is completed. For example, in a case where the number of reciprocations of the workpiece required for the completion of the implantation processing of the first workpiece W1 and the second workpiece W2 is three (that is, three reciprocations), the processes S34 to S44 are repeated three times. In this case, a process in which the first workpiece W1 reciprocates once to be irradiated with the ion beam and a process in which the second workpiece W2 reciprocates once to be irradiated with the ion beam are alternately executed three times each. In this case, a relative distance d between the first workpiece W1 and the second workpiece W2 can be set to be as small as possible so that S38 and S40 can be executed simultaneously, and a relative distance d between the first workpiece W1 and the second workpiece W2 can be set to be as small as possible so that S44 and S34 can be executed simultaneously. That is, a state in which the relative distance d between the first workpiece W1 and the second workpiece W2 is set to be as small as possible can be maintained so that the first workpiece W1 and the second workpiece W2 can be reciprocated in the same direction in synchronization with each other. Accordingly, the utilization efficiency of the ion beam can be improved.

In a case where the implantation processing is completed in S46 (Y in S46), the first holding device 40 is moved to the first transport position 80 (S48) and the second holding device 42 is moved to the second transport position 82 (S50). An order of the processes S48 and S50 is not limited, and S50 may start after the start of S48 or S48 may start after the start of S50. The processes S48 and S50 may be executed simultaneously. Further, since the first holding device 40 is already disposed at the first transport position 80 in the process S38 in a case where the first retreat position is the first transport position 80, the process S48 may be omitted. Similarly, since the second holding device 42 is already disposed at the second transport position 82 in the process S44 in a case where the second retreat position is the second transport position 82, the process S50 may be omitted.

The flow shown in FIG. 11 can be repeatedly executed until implantation processes for a plurality of workpieces to be continuously processed are completed. According to the flow shown in FIG. 11, a first transport process in which the first workpiece W1 is transported onto and out of the first holding device 40 and a second transport process in which the second workpiece W2 is transported onto and out of the second holding device 42 can be executed simultaneously. Therefore, productivity can be improved. It is preferable that the flow shown in FIG. 11 is applied in a case where an implantation time taken to irradiate a workpiece with an ion beam is sufficiently short (for example, half or less) as compared to a transport time taken to transport the workpiece in and out. Further, it is also preferable that the flow shown in FIG. 11 is applied in a case where an implantation time taken to irradiate a workpiece with an ion beam is sufficiently long (for example, twice or more) as compared to a transport time taken to transport the workpiece in and out. The flow shown in FIG. 11 can also be applied in a case where an implantation time taken to irradiate a workpiece with an ion beam is substantially the same as a transport time taken to transport the workpiece in and out. However, in this case, productivity in the flow shown in FIG. 10 may be higher than that in the flow shown in FIG. 11.

A case where the beam generation device 12 generates a scanning beam using the beam scanning unit 28 and the beam collimation unit 30 has been described in the above-described embodiment. In another embodiment, the beam generation device may generate a ribbon beam. The beam generation device may include a ribbon beam generation unit instead of the beam scanning unit 28. The ribbon beam generation unit causes a spot-like ion beam to be defocused in the vertical direction to generate a ribbon beam. The ribbon beam generation unit may be formed of an electric field type beam defocusing unit or a magnetic field type beam defocusing unit.

A case where the ion beam extracted from the ion source 20 is a ribbon-like beam spreading in the horizontal direction has been described in the above-described embodiment. In another embodiment, the ion beam extracted from the ion source may be a ribbon beam spreading in the vertical direction. In this case, the front slit of the ion source has the shape of a slit of which an opening width in the vertical direction is long and an opening width in the horizontal direction is short. Similarly, the extraction electrodes of the extraction unit have the shape of a slit of which an opening width in the vertical direction is long and an opening width in the horizontal direction is short. In this case, the mass spectrometry unit is configured to deflect the ribbon beam, which spreads in the vertical direction, in the horizontal direction. In this case, the beam generation device may not include the beam scanning unit 28 and the beam collimation unit 30. In this case, the ion source and the extraction unit can be referred to as a ribbon beam generation unit for generating a ribbon beam that spreads in the vertical direction.

In another embodiment described above, the size of an irradiation range, which is irradiated with a ribbon beam spreading in the vertical direction, in the vertical direction is larger than the size of the workpiece in the vertical direction. Therefore, the beam generation device that generates a ribbon beam is configured to irradiate an irradiation range, of which the size in the vertical direction is larger than the size of the processing target surface of a workpiece in the vertical direction, with an ion beam. In the above-described embodiment, the beam generation device 12 that generates a scanning beam is configured to irradiate an irradiation range, of which the size in the vertical direction is larger than the size of the processing target surface of a workpiece in the vertical direction, with the ion beam.

A case where the plurality of holding devices 40 and 42 are provided in the implantation processing chamber 14 has been described in the above-described embodiment. In another embodiment, only a single holding device may be provided in the implantation processing chamber 14. The single holding device may have the same configuration as any one of the first holding device 40 and the second holding device 42 described above.

A case where the scanning direction of the scanning beam SB is the vertical direction has been described in the above-described embodiment. In another embodiment, the scanning direction of the scanning beam SB may be inclined with respect to the vertical direction. In this case, the beam scanning unit 28, the beam collimation unit 30, the acceleration/deceleration unit 32, and the energy filter unit 34 are disposed at positions rotated about the beamline A extending in the z2 direction (for example, at positions downstream of the mass spectrometry unit 24 and upstream of the implantation processing chamber 14) as a rotation axis (that is, in an inclined direction). Only the beam scanning unit 28 and the beam collimation unit 30 may be disposed to be rotated, and at least one of the acceleration/deceleration unit 32 and the energy filter unit 34 may be disposed not to be rotated. In this case, it is preferable that the scanning direction of the scanning beam SB is within 45 degrees from the vertical direction.

A case where the first holding device 40 and the second holding device 42 are moved in the horizontal direction has been described in the above-described embodiment. In another embodiment, the moving direction of the first holding device 40 and the second holding device 42 may not be the horizontal direction and may be inclined with respect to the horizontal direction. The moving direction of the first holding device 40 and the second holding device 42 may be a direction different from the horizontal direction, and may be any direction crossing the scanning beam.

An aspect of the present disclosure is as follows.

1. An ion implanter including:

an ion source that generates ions;

an extraction unit that extracts the ions from the ion source to generate an ion beam;

a beam scanning unit that is configured to perform reciprocating scanning in a scanning direction, which is different from a horizontal direction, with the ion beam to generate a scanning beam; and

a holding device that is configured to hold a workpiece and to reciprocate the workpiece, which is held by the holding device, in a direction crossing the scanning beam.

2. The ion implanter according to claim 1,

in which the holding device is configured to reciprocate the workpiece, which is held by the holding device, in the horizontal direction.

3. The ion implanter according to claim 1 or 2, in which the scanning direction is a direction within 45 degrees from a vertical direction.

4. The ion implanter according to claim 1 or 2,

in which the scanning direction is a vertical direction.

5. The ion implanter according to any one of claims 1 to 4,

in which the ion source includes a front slit through which the ions extracted by the extraction unit pass, and

an opening width of the front slit in the horizontal direction is larger than an opening width of the front slit in a vertical direction.

6. The ion implanter according to claim 5,

in which the ion source includes an arc chamber that includes an internal space and the front slit for extracting the ions from plasma generated in the internal space, and a magnet device that applies a magnetic field parallel to the horizontal direction to the internal space.

7. The ion implanter according to claim 5 or 6,

in which the extraction unit includes an extraction electrode including an extraction opening through which the ion beam passes, and

an opening width of the extraction opening in the horizontal direction is larger than an opening width of the extraction opening in the vertical direction.

8. The ion implanter according to any one of claims 1 to 7, further including:

a mass spectrometry unit that is provided between the extraction unit and the beam scanning unit and deflects the ion beam in the horizontal direction.

9. The ion implanter according to claim 8,

in which the mass spectrometry unit includes a magnet device that applies a magnetic field, which is parallel to a vertical direction, to the ion beam.

10. The ion implanter according to claim 8 or 9, further including:

a magnetic shield that is provided between the extraction unit and the mass spectrometry unit and includes a passage opening through which the ion beam passes.

11. The ion implanter according to any one of claims 8 to 10, further including:

a beam shaping unit that is provided between the mass spectrometry unit and the beam scanning unit and includes at least one lens device for adjusting at least one of a cross-sectional shape and a convergence/divergence angle of the ion beam.

12. The ion implanter according to any one of claims 1 to 11, further including:

a beam collimation unit that is provided on a downstream side of the beam scanning unit and collimates the scanning beam.

13. The ion implanter according to any one of claims 1 to 12, further including:

an energy filter unit that includes a deflector deflecting the scanning beam in the horizontal direction and an energy resolving aperture provided on a downstream side of the deflector.

14. The ion implanter according to claim 13,

in which the deflector includes a pair of electrodes that faces each other with the scanning beam interposed therebetween, and a power supply that applies a DC voltage to the pair of electrodes.

15. The ion implanter according to claim 14,

in which the pair of electrodes of the deflector is disposed to face each other in the horizontal direction.

16. The ion implanter according to claim 14,

in which the pair of electrodes of the deflector is disposed to face each other in a direction perpendicular to the scanning direction.

17. An ion implantation method including:

generating ions using an ion source;

extracting the ions from the ion source to generate an ion beam;

performing reciprocating scanning in a scanning direction, which is different from a horizontal direction, with the ion beam to generate a scanning beam; and reciprocating a workpiece in a direction crossing the scanning beam.

Another aspect of the present disclosure is as follows.

18. An ion implanter including:

a beam generation device that is configured to generate an ion beam with which a workpiece is to be irradiated and to irradiate an irradiation range, of which a size in a vertical direction is larger than a size of a processing target surface of the workpiece, with the ion beam;

a first holding device that is configured to hold a first workpiece and to reciprocate the first workpiece in a horizontal direction such that the first workpiece held by the first holding device crosses the irradiation range; and

a second holding device that is configured to hold a second workpiece and to reciprocate the second workpiece in the horizontal direction such that the second workpiece held by the second holding device crosses the irradiation range.

19. The ion implanter according to claim 18,

in which the first holding device is configured to be movable between a first implantation position at which the first workpiece is irradiated with the ion beam and a first transport position at which the first workpiece is transported onto the first holding device or out of the first holding device, and

the second holding device is configured to be movable between a second implantation position at which the second workpiece is irradiated with the ion beam and a second transport position at which the second workpiece is transported onto the second holding device or out of the second holding device.

20. The ion implanter according to claim 19,

in which the first implantation position and the second implantation position are located between the first transport position and the second transport position.

21. The ion implanter according to claim 19 or 20,

in which a first movement range in which the first holding device reciprocates the first workpiece at the first implantation position and a second movement range in which the second holding device reciprocates the second workpiece at the second implantation position overlap with each other as viewed in a beam traveling direction.

22. The ion implanter according to claim 21,

in which the first movement range is common to the second movement range.

23. The ion implanter according to any one of claims 19 to 22,

in which a position of the first workpiece, which is held by the first holding device at the first implantation position, in the vertical direction is common to a position of the second workpiece, which is held by the second holding device at the second implantation position, in the vertical direction.

24. The ion implanter according to any one of claims 19 to 23,

in which a position of the first workpiece, which is held by the first holding device at the first implantation position, in a beam traveling direction is common to a position of the second workpiece, which is held by the second holding device at the second implantation position, in the beam traveling direction.

25. The ion implanter according to any one of claims 19 to 24,

in which the first holding device is configured to be immovable to the second transport position, and the second holding device is configured to be immovable to the first transport position.

26. The ion implanter according to any one of claims 18 to 25,

in which the first holding device and the second holding device are movable in the same direction.

27. The ion implanter according to any one of claims 18 to 26,

in which the first holding device and the second holding device are simultaneously movable in the same direction while maintaining a relative distance between the first workpiece held by the first holding device and the second workpiece held by the second holding device.

28. The ion implanter according to any one of claims 18 to 27,

in which the first holding device and the second holding device are movable along a common guide rail.

29. The ion implanter according to any one of claims 18 to 28,

in which the first holding device includes a first vertical angle adjustment mechanism that adjusts an orientation of the first workpiece in the vertical direction and a first horizontal angle adjustment mechanism that adjusts an orientation of the first workpiece in the horizontal direction, and

the second holding device includes a second vertical angle adjustment mechanism that adjusts an orientation of the second workpiece in the vertical direction and a second horizontal angle adjustment mechanism that adjusts an orientation of the second workpiece in the horizontal direction.

30. The ion implanter according to any one of claims 18 to 28,

in which the first holding device includes a first vertical angle adjustment mechanism that is rotated about a rotation axis extending in the horizontal direction to adjust an orientation of the first workpiece, and a first horizontal angle adjustment mechanism that is rotated about a rotation axis extending in the vertical direction to adjust an orientation of the first workpiece, and

the second holding device includes a second vertical angle adjustment mechanism that is rotated about a rotation axis extending in the horizontal direction to adjust an orientation of the second workpiece, and a second horizontal angle adjustment mechanism that is rotated about a rotation axis extending in the vertical direction to adjust an orientation of the second workpiece.

31. The ion implanter according to any one of claims 18 to 28,

in which the first holding device includes a first vertical angle adjustment mechanism that adjusts an orientation of the first workpiece, and the first vertical angle adjustment mechanism adjusts the orientation of the first workpiece such that the processing target surface of the first workpiece is oriented along the horizontal direction in a case where the first workpiece is to be transported in or out, and adjusts the orientation of the first workpiece such that the processing target surface of the first workpiece is oriented not along the horizontal direction in a case where the first workpiece is to be irradiated with the ion beam, and

the second holding device includes a second vertical angle adjustment mechanism that adjusts an orientation of the second workpiece, and the second vertical angle adjustment mechanism adjusts the orientation of the second workpiece such that the processing target surface of the second workpiece is oriented along the horizontal direction in a case where the second workpiece is to be transported in or out, and adjusts the orientation of the second workpiece such that the processing target surface of the second workpiece is oriented not along the horizontal direction in a case where the second workpiece is to be irradiated with the ion beam.

32. The ion implanter according to any one of claims 18 to 31,

in which the first holding device includes a first horizontal angle adjustment mechanism that adjusts an orientation of the first workpiece in the horizontal direction and a first twist mechanism that adjusts a twist angle of the first workpiece, and

the second holding device includes a second horizontal angle adjustment mechanism that adjusts an orientation of the second workpiece in the horizontal direction and a second twist mechanism that adjusts a twist angle of the second workpiece.

33. The ion implanter according to any one of claims 18 to 32,

in which the beam generation device includes a beam scanning unit that performs reciprocating scanning with the ion beam over the irradiation range.

34. The ion implanter according to any one of claims 18 to 32,

in which the beam generation device includes a ribbon beam generation unit that generates a ribbon beam having a beam size corresponding to a size of the irradiation range.

35. An ion implantation method including:

generating an ion beam with which a workpiece is to be irradiated;

irradiating an irradiation range, of which a size in a vertical direction is larger than a size of a processing target surface of the workpiece, with the ion beam;

causing a first holding device to hold a first workpiece;

reciprocating the first workpiece in a horizontal direction using the first holding device such that the first workpiece crosses the irradiation range;

causing a second holding device to hold a second workpiece; and

reciprocating the second workpiece in the horizontal direction using the second holding device such that the second workpiece crosses the irradiation range.

Although the present disclosure has been described above with reference to each of the above-described embodiments, the present disclosure is not limited to each of the above-described embodiments and the configuration of the respective embodiments described above may be combined as appropriate or may be replaced. Further, it is also possible to appropriately rearrange combinations in each embodiment or the order of the processing, and to add modifications, such as various design changes, to the embodiments, based on the knowledge of those skilled in the art. Further, it is also possible to rearrange the combination in each of the above-described embodiments or the order of processing as appropriate or to add modifications such as various design changes to the embodiment, based on the knowledge of those skilled in the art. The scopes of the ion implanter and the ion implantation method according to the embodiments of the present disclosure may also include embodiments to which such rearrangements or modifications are added.

The embodiment of the present disclosure may adopt a form of a computer program including one or more computer-readable sequences for describing the methods according to the present disclosure, or may adopt a form of a non-transitory and tangible storage medium (for example, a non-volatile memory, a magnetic tape, a magnetic disk, or an optical disk) in which such a computer program is stored. The processor may realize the method according to the embodiment of the present disclosure by executing such a computer program.

According to the non-limiting exemplary embodiment of the present invention, it is possible to provide a technique for improving the productivity of an ion implantation process.

It should be understood that the invention is not limited to the above-described embodiment, but may be modified into various forms on the basis of the spirit of the invention. Additionally, the modifications are included in the scope of the invention.

What is claimed is:

1. An ion implanter comprising:
an ion source that generates ions;
an extraction unit that extracts the ions from the ion source to generate an ion beam;
a mass spectrometry unit that deflects the ion beam in a horizontal direction;
a beam scanning unit that is configured to perform reciprocating scanning in a scanning direction, which is different from the horizontal direction, with the ion beam having passed through the mass spectrometry unit to generate a scanning beam; and
a holding device that is configured to hold a workpiece and to reciprocate the workpiece, which is held by the holding device, in a direction crossing the scanning beam.

2. The ion implanter according to claim 1,
wherein the mass spectrometry unit includes a magnet device that applies a magnetic field, which is parallel to a vertical direction, to the ion beam.

3. The ion implanter according to claim 1, further comprising:
a magnetic shield that is provided between the extraction unit and the mass spectrometry unit and includes a passage opening through which the ion beam passes.

4. The ion implanter according to claim 1, further comprising:
a beam shaping unit that is provided between the mass spectrometry unit and the beam scanning unit and includes at least one lens device for adjusting at least one of a cross-sectional shape and a convergence/divergence angle of the ion beam.

5. The ion implanter according to claim 1,
wherein the ion source includes a front slit through which the ions extracted by the extraction unit pass, and
an opening width of the front slit in the horizontal direction is larger than an opening width of the front slit in a vertical direction.

6. The ion implanter according to claim 5,
wherein the ion source includes an arc chamber that includes an internal space and the front slit for extracting the ions from plasma generated in the internal space, and a magnet device that applies a magnetic field parallel to the horizontal direction to the internal space.

7. The ion implanter according to claim 5,
wherein the extraction unit includes an extraction electrode including an extraction opening through which the ion beam passes, and
an opening width of the extraction opening in the horizontal direction is larger than an opening width of the extraction opening in the vertical direction.

8. The ion implanter according to claim 1,
wherein the holding device is configured to reciprocate the workpiece, which is held by the holding device, in the horizontal direction.

9. The ion implanter according to claim 1,
wherein the scanning direction is a direction within 45 degrees from a vertical direction.

10. The ion implanter according to claim 1,
wherein the scanning direction is a vertical direction.

11. The ion implanter according to claim 1, further comprising:
a beam collimation unit that is provided on a downstream side of the beam scanning unit and collimates the scanning beam.

12. The ion implanter according to claim 1, further comprising:
an energy filter unit that includes a deflector deflecting the scanning beam in the horizontal direction and an energy resolving aperture provided on a downstream side of the deflector.

13. The ion implanter according to claim 12,
wherein the deflector includes a pair of electrodes that faces each other with the scanning beam interposed therebetween, and a power supply that applies a DC voltage to the pair of electrodes.

14. The ion implanter according to claim 13,
wherein the pair of electrodes of the deflector is disposed to face each other in the horizontal direction.

15. The ion implanter according to claim 13,
wherein the pair of electrodes of the deflector is disposed to face each other in a direction perpendicular to the scanning direction.

16. An ion implantation method comprising:
generating ions using an ion source;
extracting the ions from the ion source to generate an ion beam;
deflecting the ion beam in a horizontal direction to perform mass spectrometry;
performing reciprocating scanning in a scanning direction, which is different from the horizontal direction, with the ion beam having been subjected to the mass spectrometry to generate a scanning beam; and
reciprocating a workpiece in a direction crossing the scanning beam.
